(19) United States
(12) Patent Application Publication
(10) Pub. No.: US 2024/0035200 A1
(43) Pub. Date: Feb. 1, 2024

(54) METHOD FOR GROWING SINGLE CRYSTALS

(71) Applicant: EBNER Industrieofenbau GmbH, Leonding (AT)

(72) Inventors: Robert EBNER, Leonding (AT); Kanaparin ARIYAWONG, Leonding (AT); Ghassan BARBAR, Neunkirchen (DE); Chih-Yung HSIUNG, Leonding (AT)

(73) Assignee: EBNER Industrieofenbau GmbH, Leonding (AT)

(21) Appl. No.: 18/028,686

(22) PCT Filed: Sep. 23, 2021
(86) PCT No.: PCT/AT2021/060344

§ 371 Date: Mar. 27, 2023

(30) Foreign Application Priority Data
Sep. 28, 2020 (AT) A 50822/2020

(51) Int. Cl. C30B 35/00; C30B 25/18; C30B 29/60; C30B 29/36; C30B 33/08; C30B 33/02

(52) U.S. Cl. CPC C30B 35/002; C30B 25/183; C30B 29/60; C30B 29/36; C30B 33/08; C30B 33/02

(57) ABSTRACT

A device for growing single crystals, in particular of silicon carbide, includes a crucible, which crucible defines an outer lateral surface and moreover delimits an accommodation space with an axial extension between a bottom section and an opening section, wherein the accommodation space is designed for growing the single crystals, wherein the device includes at least one seed crystal layer, wherein the seed crystal layer is assembled from multiple seed crystal plates in a tessellated manner.

The invention relates to a device for growing single crystals, in particular of silicon carbide (SiC), comprising a crucible, which crucible defines an outer lateral surface and moreover delimits an accommodation space with an axial extension between a bottom section and an opening section, wherein the accommodation space is designed for growing single crystals, wherein the device has at least one seed crystal layer.

Moreover, the invention relates to a method for producing a seed crystal layer, in particular of silicon carbide.

For many technical applications, single crystals are nowadays produced on an industrial scale. Based on the phase transitions leading to the crystal, a distinction can be made between the growth from the melt, from the solution and from the gas phase. In the case of growth from the gas phase, further distinctions can be made between the production methods of the sublimation and/or the physical vapor deposition and the method of the chemical vapor deposition. In the case of the physical vapor deposition, the substance to be grown is vaporized by means of heating, so that it transitions into the gas phase. Given suitable conditions, the gas can resublimate on a seed crystal, whereby a growth of the crystal takes place. The raw material (powder or granules) usually present in a polycrystalline form is thus recrystallized. The chemical vapor deposition works in a similar manner. In this process, the transition of the substance to be grown into the gas phase is only possible by means of an auxiliary substance, to which the substance chemically binds itself, since the vapor pressure would be too low otherwise. Thus, a higher transport rate towards the seed crystal is achieved in combination with the auxiliary substance.

A great interest is taken in silicon carbide single crystals, particularly because of their semi-conductor properties. Their production is carried out in furnaces with a crucible, in which the silicon carbide raw material is heated, and a seed crystal, on which the further crystal growth takes place by means of accumulation. Moreover, the interior of the process chamber is evacuated. The material used for the innermost process chamber with the crucible is graphite. Usually, the seed crystal is located directly on a cover of a crucible containing the raw material.

A problem, which occurs in known methods, is that the size of the area of the seed crystals is usually limited, which is why only ingots made of single crystals with a limited diameter can be produced.

Therefore, it is the object of the invention to overcome the disadvantages of the prior art and to make the production of ingots and, in further consequence, of wafers with a larger diameter possible.

This object is achieved according to the invention with a device of the initially mentioned type, by the seed crystal layer being assembled from multiple seed crystal plates in a tessellated manner.

The solution according to the invention makes the production of ingots and, in further consequence, of wafers made of silicon carbide with any desired diameter possible.

In order to obtain single crystals of very high quality, it is particularly advantageous of the crystal orientations of the seed crystal plates in the seed crystal layer are oriented uniformly.

An assembly of the seed crystal layer is significantly simplified by the seed crystal plates each having a polygonal, in particular hexagonal, circumferential contour.

According to an advantageous variant of the invention, it may be provided that the seed crystal plates are connected to a cover of the crucible, with or without intermediate layers arranged between the seed crystal plates and the cover.

However, the seed crystal plates may also be applied to a substrate separate from the cover.

It has proven particularly advantageous that the substrate is formed from graphite.

In order to obtain a good mechanical stability and a self-supporting seed crystal layer, it may be provided that the seed crystal layer has a thickness of between 350 and 2000 μm.

According to an advantageous advancement of the invention, it may be provided that the seed crystal layer has a mass per unit area of between 2.20 kg/m² and 3.90 kg/m².

Furthermore, it has proven advantageous that the seed crystal layer comprises at least one polished and/or sanded and/or dry-etched surface.

It has proven particularly favorable, regarding the quality of the grown single crystals, that the seed crystal layer has an area-related roughness value of between 10 nm and 0.01 nm.

Furthermore, the seed crystal layer may be doped with at least one material, in particular SiC or AlN.

The above-mentioned object can also be achieved according to the invention with a method of the initially mentioned type, by the seed crystal layer being assembled from multiple seed crystal plates in a tessellated manner.

It has proven particularly advantageous that the individual seed crystal plates are made from wafers.

The seed crystal plates may be applied to a substrate, with or without the arrangement of at least one intermediate layer between the substrate and the seed crystal plates.

Moreover, at least one epitaxy layer of a monocrystalline silicon carbide may be applied to the seed crystal plates, in particular by means of a CVD method. The seed crystal plates can be held together by the applied epitaxy layer.

It has also proven particularly advantageous that the individual seed crystal plates have an area-related roughness value of between 10 nm and 0.01 nm. By forming very smooth surfaces, the seed crystal plates may also adhere to a substrate, for example a cover of the crucible, without further intermediate layers, in particular adhesion agent layers.

Furthermore, the seed crystal layer may be dry-etched, sanded and/or polished.

In order to eliminate any potential defects, the assembled seed crystal layer may be subjected to a heat treatment.

Furthermore, it may be provided that the seed crystal layer is provided with at least one material, in particular SiC or AlN, in a sublimation atmosphere.

For the purpose of better understanding of the invention, it will be elucidated in more detail by means of the figures below.

These show in a respectively very simplified schematic representation:

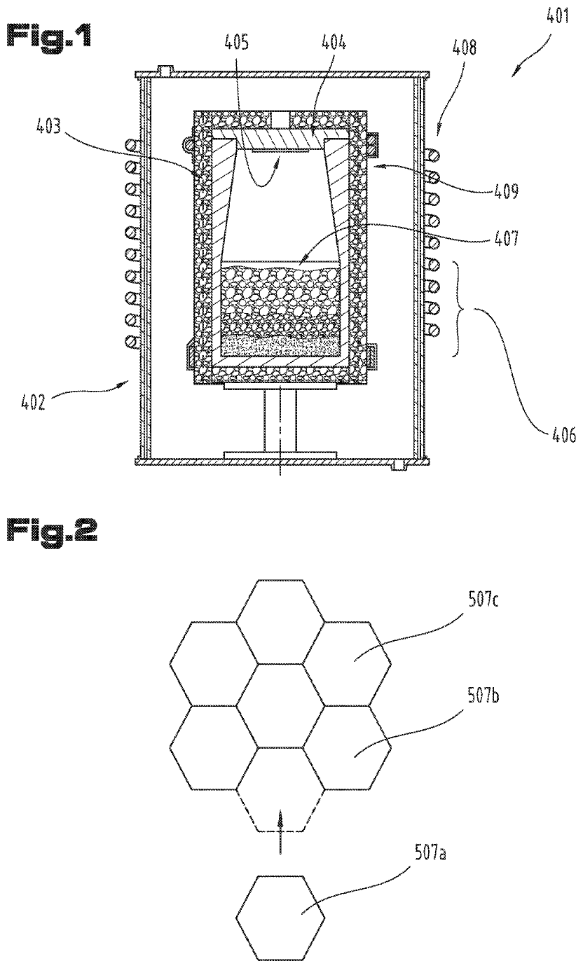

FIG. 1 a first variant of a device according to the invention;

FIG. 2 a seed crystal layer according to the invention;

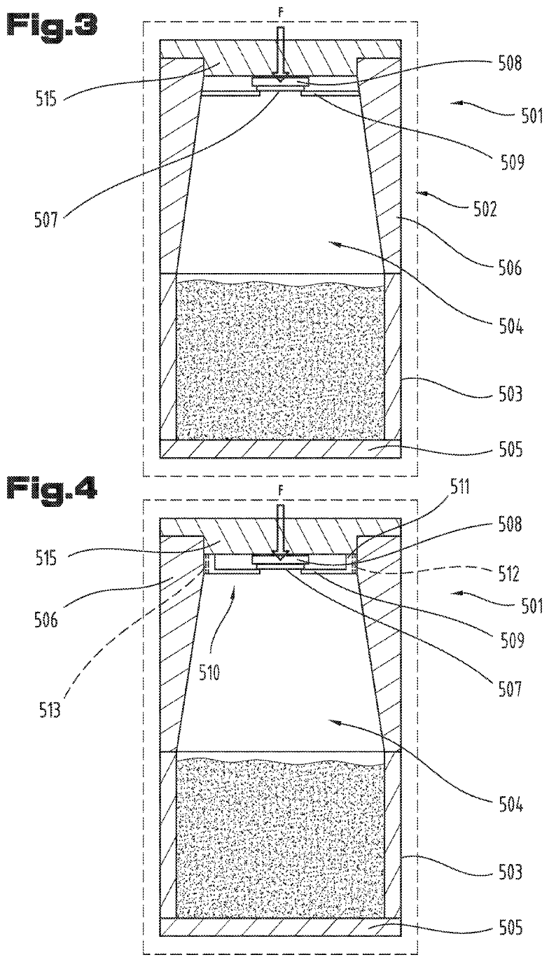

FIG. 3 a second variant of a device according to the invention;

FIG. 4 a third variant of a device according to the invention;

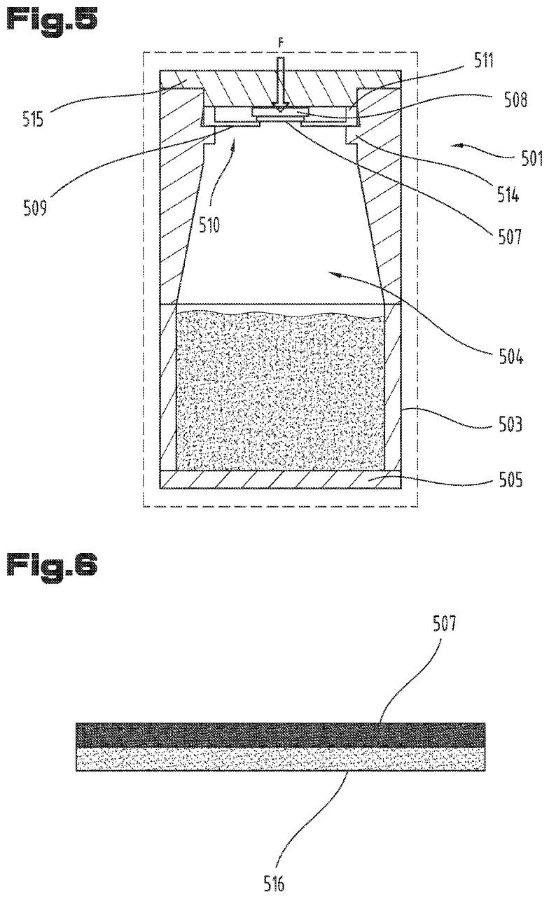

FIG. 5 a fourth variant of a device according to the invention, and

FIG. 6 a section through seed crystal layer arranged on a substrate.

First of all, it is to be noted that in the different embodiments described, equal parts are provided with equal reference numbers and/or equal component designations, where the disclosures contained in the entire description may be analogously transferred to equal parts with equal reference numbers and/or equal component designations. Moreover, the specifications of location, such as at the top, at the bottom, at the side, chosen in the description refer to the directly described and depicted figure and in case of a change of position, these specifications of location are to be analogously transferred to the new position.

FIG. 1 shows a device 401 according to the invention in the form of a furnace for producing single crystals by means of physical vapor deposition. The furnace comprises a chamber 402, which can be evacuated, with a crucible 403 accommodated therein. The crucible 403 is designed to be essentially pot-shaped, wherein an upper end region is closed by a cover 404. A bottom side of the cover 404 of the crucible 403 is, in this regard, usually configured to fasten a seed crystal 405. In a bottom region 406 of the crucible 403, a base material 407 is present, which serves as a raw material for the crystal growth on the seed crystal 405, and which is gradually consumed during the production process.

The transition of the base material 407 into the gas phase is achieved by heating with the aid of a heater 408. According to this exemplary embodiment, the heating of the base material 407 and the crucible 403 by means of the heater 408 is carried out inductively. The crucible 403 arranged in the chamber 402 is moreover enveloped by an insulation 409 for thermal insulation. By means of the insulation 409, thermal losses from the crucible 403 are simultaneously prevented, and a heat distribution favorable for the growth process of the crystal on the seed crystal 405 is achieved in the interior of the crucible 403.

The material for the chamber 402 is preferably a glass material, in particular a quartz glass. The crucible 403 and the insulation 409 surrounding it preferably consist of graphite, wherein the insulation 409 is formed by a graphite felt.

Because atoms and/or molecules of the base material 407 transition into the gas phase due to heating of the base material 407, the atoms and/or molecules can diffuse to the seed crystal 405 in the interior of the crucible 403 and accumulate thereon, whereby the crystal growth takes place.

According to FIG. 2, the seed crystal layer 507 is assembled from multiple seed crystal plates 507a, 507b, 507c in a tessellated manner. In this regard, the individual seed crystal plates 507a, 507b, 507c are preferably assembled such that the crystal orientations of the seed crystal plates 507a, 507b, 507c are oriented uniformly and a closed flat surface is formed. It has proven favorable in this regard that the individual seed crystal plates are made from wafers.

At least one epitaxy layer of monocrystalline silicon carbide may be applied to the seed crystal plates 507a, 507b, 507c, in particular by means of a CVD method. The application of the epitaxy layer, in addition to the arrangement and connection of the individual seed crystal plates 507a, 507b, 507c on a substrate, constitutes a possibility to connect the individual seed crystal plates 507a, 507b, 507c to one another. The assembled seed crystal layer 507 may be subjected to a heat treatment to eliminate any possible defects. This way, the seed crystal layer 507 may be heated, for example, to a temperature of more than 1200° C., and this temperature may be maintained between 10 min and 3 h. Afterwards, a cooling and thermal annealing of defects may take place at a temperature of less than 800° C. The heat treatment may take place in an inert gas atmosphere, for example.

Furthermore, the seed crystal layer 507 may be provided with a material, in particular SiC or AlN, in a sublimation atmosphere. The seed crystal layer may, in particular, be doped with the material.

As can further be seen in FIG. 2, the seed crystal plates 507a, 507b, 507c may each have a polygonal, in particular hexagonal, circumferential contour.

The seed crystal plates 507a, 507b, 507c may be connected to the cover 404 of the crucible 403 with or without intermediate layers arranged between the seed crystal plates and the cover, as is shown for example in FIG. 1. However, the seed crystal plates 507a, 507b, 507c may also be applied to a substrate separate from the cover 403, as is shown in FIG. 6.

The seed crystal layer 507 has a preferred thickness of 350-2000 μm and a preferred mass per unit area of between 2.20 kg/m² and 3.90 kg/m².

Moreover, the seed crystal layer 507 may have one or two polished and/or lapped surfaces. It has proven particularly favorable that the seed crystal layer has an area-related roughness value of between 10 nm and 0.01 nm. The area-related roughness value is defined, for example, in the EN ISO 25178 standard.

For producing the seed crystal layer 507, the seed crystal plates 507a, 507b, 507c are assembled in a tessellated manner.

According to FIG. 3, the device 501 according to the invention for growing single crystals, in particular single crystals of silicon carbide, comprises a crucible 502. The crucible 502 defines an outer lateral surface 503 and moreover delimits an accommodation space 504 with an axial extension between a bottom section 505 and an opening section 506. The accommodation space 504 is designed for growing the crystals, wherein at least one seed crystal layer 507 is arranged in the opening section 506. The crucible 502 may be arranged in a chamber equivalent to the chamber 402 and also be heated inductively.

Contrary to the embodiment according to FIG. 1, the seed crystal layer 507 is weighted down by means of a weighting mass 508 on a side facing away from the accommodation space 504 and is fixed in its position against at least one holding section 509 arranged in the opening section by means of the weight force of the weighting mass 508. It is preferably provided that the seed crystal layer 507 is locked into position only by means of the weight force of the weighting mass 508. Apart from this, the device 501 may be designed like the furnace of FIG. 2.

As can further be seen in FIG. 3, the seed crystal layer 507 may contact the at least one holding section 509 with at least an outer edge region.

The holding section 509 may be designed to extend circumferentially around an opening 510 of the opening section 506.

According to FIGS. 4 and 5, the holding section 509 may be formed at least by a section of the mount 510 having an annular or tubular base body 511, the section facing a longitudinal central axis of the crucible, wherein the holding section 509 protrudes from the base body 511. The mount 510 may be screwed into the crucible 502 as is shown in FIG. 4, or inserted as is shown in FIG. 5.

According to the embodiment shown in FIG. 4, the mount 510 may have an external thread 512 on a lateral surface of the base body 511, wherein a lateral surface delimiting the opening may have an internal thread 513 corresponding to the external thread.

According to FIG. 5, the mount 510 inserted into the crucible may be supported on a projection 514 of the crucible 502. The projection 514 may be designed, for example, to extend circumferentially around the opening of the opening section 506.

The weighting mass 508 may be arranged between the seed crystal layer 507 and a cover 515 of the crucible 502, wherein the weighting mass 508 and the cover 515 are formed separately from one another. The weighting mass 508 is preferably arranged loosely between the cover 515 and the seed crystal layer 507.

The seed crystal layer 507 may be designed as a mechanically self-supporting layer or also be applied to a carrier substrate 516, as it is shown in FIG. 6. If the seed crystal layer 507 is applied to a carrier substrate, the weighting mass 508 may rest on the carrier substrate 516. Graphite has proven particularly suited for being the carrier substrate.

The weighting mass 508 and/or the mount 510 may be made of metal, ceramics, mineral or plastics. Fireproof materials, carbides, oxides, or nitrides have proven particularly suitable.

Finally, as a matter of form, it should be noted that for ease of understanding of the structure, elements are partially not depicted to scale and/or are enlarged and/or are reduced in size.

### LIST OF REFERENCE NUMBERS

401 Device 510 Mount
402 Chamber 511 Base body
403 Crucible 512 External thread
404 Cover 513 Internal thread
405 Seed crystal 514 Projection
406 Bottom section 515 Cover
407 Base material
408 Heater
409 Insulation
410 Lumps
411 Powder
412 Height
413 Pellet
414 Silicon
415 Axis
416 Bearing
417 Storage container
418 Feed line
501 Device
502 Crucible
503 Lateral surface
504 Accommodation space
505 Bottom section
506 Opening section
507 Seed crystal
507a-c Seed crystal plates
508 Weighting mass
509 Holding section

1. A device (401, 501) for growing single crystals, in particular of silicon carbide, comprising a crucible (403, 502), which crucible (403, 502) defines an outer lateral surface (503) and moreover delimits an accommodation space (504) with an axial extension between a bottom section (406, 505) and an opening section (506), wherein the accommodation space (504) is designed for growing the single crystals, wherein the device comprises at least one seed crystal layer (507), wherein the seed crystal layer (405, 507) is assembled from multiple seed crystal plates (507a, 507b, 507c) in a tessellated manner.

2. The device according to claim 1, wherein the crystal orientations of the seed crystal plates (507a, 507b, 507c) in the seed crystal layer are oriented uniformly.

3. The device according to claim 1, wherein the seed crystal plates (507a, 507b, 507c) each have a polygonal, in particular hexagonal, circumferential contour.

4. The device according to claim 1, claim 1, wherein the seed crystal plates (507a, 507b, 507c) are connected to a cover (404) of the crucible (403), with or without intermediate layers arranged between the seed crystal plates and the cover.

5. The device according to claim 1, wherein the seed crystal plates (507a, 507b, 507c) are applied to a substrate (516) separate from the cover (403, 515).

6. The device according to claim 1, wherein the substrate is formed from graphite.

7. The device according to claim 1, wherein the seed crystal layer has a thickness of between 350 and 2000 μm.

8. The device according to claim 1, wherein the seed crystal layer has a mass per unit area of between 2.20 kg/m² and 3.90 kg/m².

9. The device according to claim 1, wherein the seed crystal layer comprises at least a polished and/or dry-etched and/or sanded surface.

10. The device according to claim 1, wherein the seed crystal layer has an area-related roughness value of between 10 nm and 0.01 nm.

11. The device according to claim 1, wherein the seed crystal layer (507) is doped with at least one material, in particular SiC or AlN.

12. A method for producing a seed crystal layer, in particular of silicon carbide, wherein the seed crystal layer (507) is assembled from multiple seed crystal plates (507a, 507b, 507c) in a tessellated manner.

13. The method according to claim 12, wherein the individual seed crystal plates (507a, 507b, 507c) are made from wafers.

14. The method according to claim 12 or 13, wherein the seed crystal plates (507a, 507b, 507c) are applied to a substrate, with or without the arrangement of at least one intermediate layer between the substrate and the seed crystal plates.

15. The method according to claim 12, wherein at least one epitaxy layer of a monocrystalline silicon carbide is applied to the seed crystal plates (507a, 507b, 507c), in particular by means of a CVD method.

16. The method according to claim 12, wherein the seed crystal layer is sanded, polished and/or dry-etched.

17. The method according to claim 12, wherein the assembled seed crystal layer (507) is subjected to a heat treatment.

18. The method according to claim 12, wherein the seed crystal layer (507) is provided with at least one material, in particular SiC or AlN, in a sublimation atmosphere.
